(19) United States
(12) Patent Application Publication
(10) Pub. No.: US 2024/0047204 A1
(43) Pub. Date: Feb. 8, 2024

(54) Direct Preparation of Pseudo-Graphene on a Silicon Carbide Crystal Substrate

(71) Applicant: Kyusang Lee, Charlottesville, VA (US)

(72) Inventor: Kyusang Lee, Charlottesville, VA (US)

(21) Appl. No.: 18/209,968

(22) Filed: Jun. 14, 2023

Related U.S. Application Data
(63) Continuation of application No. 17/880,692, filed on Aug. 4, 2022.

(51) Int. Cl. H01L 21/02

(52) U.S. Cl. CPC H01L 21/0254; H01L 21/02568; H01L 21/0262; H01L 21/02595

(57) ABSTRACT

Methods of fabricating a semiconductor structure that includes a pseudo-graphene (PG) layer formed on an SiC substrate to form a reusable PG/SiC substrate for both remote epitaxy and van der Waals epitaxy. Disclosed are two different processes of fabricating a pseudo-graphene layer on an SiC substrate: (1) plasma dry etching after graphitization of the SiC substrate to remove the epitaxial graphene layer and expose the PG; and (2) direct thermalization in which the graphitization process is managed so that substantially only a pseudo-graphene layer forms on the SiC substrate. In both processes, a high-quality PG layer is formed on the SiC substrate. Advantageously, the methods described do not require exfoliation processes to fabricate the PG/SiC substrate, thereby avoiding problems such as contamination by materials (e.g., Ni) that may otherwise damage the PG surface.

### CROSS-REFERENCE TO RELATED APPLICATIONS

The present continuation application claims priority to the following patent application, assigned to the assignee of the present invention, the contents of which are incorporated by reference: U.S. patent application Ser. No. 17/880,692, filed Aug. 4, 2022, entitled “Monolithic Remote Epitaxy of Compound Semiconductors and 2D Materials”.

### BACKGROUND

### (1) Technical Field

The present invention relates to semiconductor fabrication processes, and particularly to processes for creating re-usable semiconductor substrates that are useful for epitaxially forming membranes that can be removed from the substrate.

### (2) Background

Much of the electronics age has relied upon semiconductor integrated circuits (ICs) based on silicon. In over half a century, engineers and manufacturers have made vast strides in silicon manufacturing, IC design, and semiconductor applications. These decades of development have resulted in such economies of scale that silicon-based ICs are very inexpensive and the tools and techniques for manufacturing such ICs are well-known and wide-spread. However, Moore's Law suggests that researchers may be reaching the theoretical limits of silicon-based semiconductors.

Accordingly, research scientists and semiconductor manufacturers have long searched for more robust alternatives to silicon for numerous applications. A strong contending alternative to silicon has emerged: the nitrides of periodic table group III metal elements (commonly known as “III-nitride” semiconductors), which possess a number of properties that are simply not accessible in any other family of semiconductors, including a high dielectric breakdown voltage and a bandgap that spans from the infrared to the deep ultraviolet.

III-nitride semiconductors are a subset of III-V semiconductors, which comprise semiconductor alloys that include an element having three (III) valence electrons and an element having five (V) valence electrons. Group III elements include boron (B), aluminum (Al), gallium (Ga), and indium (In), while group V elements include nitrogen (N), phosphorous (P), arsenic (As), and antimony (Sb). Binary III-nitride semiconductors include gallium nitride (GaN), aluminum nitride (AlN), indium nitride (InN), and boron nitride (BN). III-nitride semiconductor alloys may also be ternary (comprising three elements, such as AlGaN) or quaternary (comprising four elements, such as AlGaInN). Other III-nitride semiconductors include, but are not limited to, hexagonal BN, AlₓGa₁₋ₓN, InₓGa₁₋ₓN, BₓGa₁₋ₓN, AlₓIn_{y}Ga_{1-x-y}N, InₓAl₁₋ₓN, GaₓAl₁₋ₓN, BₓAl₁₋ₓN, InₓGa_{y}Al_{1-x-y}N, AlₓIn₁₋ₓN, GaₓIn₁₋ₓN, AlₓGa_{y}In_{1-x-y}N, h-GaₓB₁₋ₓN, and their alloys. III-nitride semiconductors crystallize in their most stable form into a wurtzite crystallographic structure with nitrogen atoms forming a hexagonal close-packed (hcp) structure and the group III atoms occupying half of the tetrahedral sites available in the hcp lattice.

A III-nitride semiconductor of particular interest is GaN. One of the most significant advantages of gallium nitride over silicon is its bandgap, which gives it various electrical properties that equip it for higher power applications. GaN has a bandgap of about 3.2 electron volts (eV) compared to about 1.1 eV for Si, and accordingly GaN-based field-effect transistors (FETs) exhibit larger breakdown voltages and more thermal stability at higher temperatures. GaN's breakdown field is about 3.3 MV/cm compared to about 0.3 MV/cm for Si, which makes GaN 10 times more capable of supporting high voltages before failing. Silicon has an electron mobility of about 1500 cm²/Vs compared to up to about 2000 cm²/Vs for GaN. Thus, electrons in GaN crystals can move over 30% faster than in Si. This higher electron mobility for GaN enables higher switching frequencies than for Si, a distinct advantage for use in high-frequency RF components. A further advantage of GaN devices is that they may be much smaller in size than Si devices having comparable performance.

A typical GaN FET includes a thin layer of aluminum gallium nitride (AlGaN) formed on top of a thin GaN crystal. A strain is created at the AlGaN/GaN interface that induces a compensating two-dimensional electron gas (2DEG). This 2DEG is used to efficiently conduct electrons when an electric field is applied across it. The 2DEG is highly conductive, in part due to the confinement of the electrons to a very small region at the AlGaN/GaN interface, which increases the mobility of electrons from about 1000 cm²/Vs in unstrained GaN to between 1500 and 2000 cm²/Vs in the 2DEG region. This characteristic allows fabrication of GaN-based High Electron Mobility Transistors (HEMTs) transistors and integrated circuits that feature higher breakdown strength, faster switching speed, and lower on-resistance than comparable silicon solutions.

Existing silicon manufacturing infrastructure may be used to grow GaN crystals on a suitable substrate, thus eliminating the need for costly specialized production sites. For example, GaN crystals may be epitaxially grown on sapphire, silicon carbide (SiC), and Si substrates, despite the mismatch of lattice constants. When epitaxially grown on a substrate, III-Nitride semiconductors can have two different orientations: metal-face (e.g., Ga-face) and nitride-face (N-face). The orientation of the final epilayer is a function of the original substrate orientation, buffer growth, and doping conditions.

Epitaxy is a process by which a deposited film is forced into a high degree of crystallographic alignment with the atomic lattice of a substrate. Several epitaxy techniques are available, including molecular beam epitaxy (MBE), epitaxial metal-organic chemical vapor deposition (MOCVD), hydride vapor phase epitaxy (HVPE) and atomic layer epitaxy (ALE). In all cases, the deposition process must be controlled enough to allow the atoms to rearrange themselves on the surface according to the lattice orientation of the substrate. Contamination of the substrate surface by impurities must be kept minimal to avoid disturbing the epitaxial alignment.

For a variety of reasons, including 1) defect problems caused by lattice constant mismatches 2) the desire to easily remove or “exfoliate” a GaN crystal from an initial substrate to create a GaN membrane, 3) provide the capability to reuse the parent substrate multiple times, and 4) reduce production costs, a technique known as “remote epitaxy” has been developed. The remote epitaxy technique grows III-nitride epilayers “remotely” on two-dimensional (2D) materials, thereby forming an interlayer between a selected substrate (e.g., SiC) and the III-nitride epilayers. Remote epitaxy can effectively grow crystalline compound semiconductor epilayers using a two-dimensional (2D) material interlayer without generating entailed dislocations as long as the potential field from the underlying substrate is strong enough to penetrate through the 2D material interlayer and affect the arrangement of deposited III-nitride material. The 2D material interlayer may be an amorphous, polycrystalline, or single crystal material, such as graphene. Further details regarding remote epitaxy may be found in U.S. patent application Ser. No. 17/880,692 referenced above.

The 2D material interlayer has a weak van der Waals interaction with the overlaying GaN-based epilayers. Unlike ionic or covalent bonds, van der Waals attraction does not result from a chemical electronic bond, and is comparatively weak and therefore more susceptible to disturbance. Accordingly, a thin-film GaN crystal or membrane comprising the GaN epilayers may be separated from the 2D material interlayer by applying a minimal or small mechanical force, generally using a layer transfer technique to attach the GaN crystal to a secondary substrate (e.g., a handle wafer or the like). The resulting free-standing GaN-based membrane can provide extra degrees of freedom in its functional implementation, while the planar form factor is compatible with modern electronic processing allowing production scalability. Additionally, the adoption of free-standing GaN-based membranes instead of bulk materials provides significant cost savings for the production of electronics, where the major cost of manufacturing is usually material related.

As noted, producing free-standing GaN-based membranes involves the separation of epitaxial crystalline GaN thin films from a 2D material interlayer formed on the initial substrate. However, the 2D material interlayer providing a van der Waals interface is susceptible to damage due to the harsh ambient environment in which crystalline semiconductor thin films are produced. Damage to the 2D material interlayer and the associated van der Waals interface often leads to failure in satisfactorily releasing the GaN-based membranes. Simultaneously achieving high-quality GaN epilayers and maintaining a robust van der Waals interface, which is a key to fabricating free-standing crystalline GaN-based membranes, has been one of the greatest challenges faced by the community. The present invention addresses this challenge.

### SUMMARY

Methods are described to fabricate a semiconductor structure that includes a pseudo-graphene layer formed on an SiC substrate. The pseudo-graphene layer may be termed a “PG” layer, and the entire semiconductor structure may be termed a “PG/SiC substrate”, a “modified substrate”, or a “template” because it provides a template form for fabricating semiconductor membranes, particularly GaN membranes. The template may be reused to make semiconductor membranes multiple times, which advantageously reduces semiconductor fabrication costs.

The description herein discloses two different processes of fabricating a pseudo-graphene layer on an SiC substrate: (1) plasma dry etching after graphitization of the SiC substrate to remove epitaxial graphene monolayers and expose the PG; and (2) direct thermalization in which the graphitization process is managed so that substantially only a pseudo-graphene layer forms on the SiC substrate. In both processes a high quality PG layer is formed on the SiC substrate.

Advantageously, the methods described do not require exfoliation processes to fabricate the PG/SiC substrate, thereby avoiding problems such as contamination by materials (e.g., Ni) that may otherwise damage the PG surface.

In a first embodiment, the method includes a method of fabricating a reusable template for forming semiconductor membranes. The method includes providing an SiC substrate, epitaxially forming a graphene structure on the substrate, and using a plasma dry etching process to remove the graphene layers and expose the pseudo-graphene layer without exfoliation of the graphene mono layers, thereby forming a PG/SiC template. The graphene structure includes a graphene layer that may include a plurality of graphene monolayers formed adjacent to each other, and a pseudo-graphene (PG) buffer layer situated between the graphene layer and the substrate. The SiC substrate has any suitable crystal structure such as 4H-SiC (0001) or 6H-SiC (0001). The orientation of the substrate's flat surface with respect to the crystal structure may be on-axis or off-axis.

In a second embodiment, the method includes a thermalization method for directly forming a PG layer on a SiC substrate to fabricate a reusable PG/SiC template. The thermalization method includes providing an SiC substrate and heating the SiC substrate to a temperature to sublimate Si from the SiC substrate, which leaves carbon on the surface of the substrate, which will become the PG layer. As the sublimation process proceeds, the PG layer begins forming and the Si sublimation process is continued until a PG layer is formed from the carbon remaining after sublimation. The Si sublimation is stopped prior to forming a graphene monolayer on the substrate, leaving the PG layer exposed, and thereby providing PG/SiC template for membrane fabrication.

The details of one or more embodiments of the invention are set forth in the accompanying drawings and the description below. Other features, objects, and advantages of the invention should be apparent from the description and drawings, and from the claims.

### BRIEF DESCRIPTION OF THE DRAWINGS

FIG. 1 is a cross-sectional view of an SiC substrate that has been cut to have a flat upper surface upon which the PG layer may be formed.

FIGS. 2 and 3 show multilayer graphene structures formed on substrates.

FIG. 4 is a cross-sectional view of a multilayer graphene structure that can be formed using Si sublimation (FIG. 3) or any other suitable technique.

FIG. 5 is a cross-sectional diagram illustrating exfoliation of EG monolayers.

FIG. 6 is a flow chart of steps to epitaxially fabricate a PG/SiC substrate using a plasma dry etching process.

FIG. 7A shows a graphitized PG/SiC substrate situated in an etching/cleaning chamber, for plasma dry etching.

FIG. 7B is a block diagram that shows components of a plasma etching/cleaning system.

FIG. 7C is a block diagram of that illustrates the plasma etching process.

FIG. 7D is a cross-sectional view of a PG/SiC substrate after the plasma etching process is complete.

FIG. 8 is flow chart of steps of a process to fabricate a PG/SiC template by utilizing Si sublimation properties and thermalization control and management to directly form a PG layer on an SiC substrate.

FIG. 9A is a block diagram that shows components of an annealing system, illustrating a cleaned SiC substrate situated within an annealing chamber.

FIG. 9B is a block diagram that shows components of an annealing system, illustrating formation of a PG layer on the upper surface of the SiC substrate while Si sublimation continues.

FIG. 9C is a cross-sectional view of a PG/SiC substrate after the direct PG layer has been formed via the Si sublimation process.

FIG. 10A is a graph showing the results of a Raman spectrograph analysis of a PG layer that remains after one use of a PG/SiC substrate made in accordance with the disclosed methods.

FIG. 10B is an associated graph of intensity as a function of Raman Shift.

FIG. 11 is an AFM image of PG/SiC substrate after exfoliation of GaN epilayers.

Like reference numbers and designations in the various drawings indicate like elements.

### DETAILED DESCRIPTION

### Overview

Methods are described to fabricate a semiconductor structure that includes a pseudo-graphene layer formed on an SiC substrate. The pseudo-graphene layer may be termed a “PG” layer, and the entire semiconductor structure may be termed a “PG/SiC substrate”, a “modified substrate”, or a “template” because it provides a template form for fabricating semiconductor membranes, particularly GaN membranes. The template may be reused to make semiconductor membranes multiple times, which advantageously reduces semiconductor fabrication costs.

The PG layer in combination with the SiC substrate provides many advantages for membrane fabrication:
The SiC crystal substrate provides a strong seed for epitaxial seeding, and the thin PG layer does not significantly interfere with the seeding quality, thereby allowing formation of high-quality epitaxial layer, particularly GaN epitaxial layers;
A epitaxial layer formed on the PG layer is easily releasable because the PG layer has a smooth initially-exposed outer surface that attaches to the epitaxial layer with only a relatively weak van der Waals force, and therefore the epitaxial layer can be removed substantially intact;
Carbon atoms in the PG are strongly attached to the underlying SiC substrate, thereby providing a damage-resistant seed layer that allows the PG to remain substantially undamaged after removal of the membrane;
The PG/SiC substrate is reusable.

The description herein discloses two different processes of fabricating a pseudo-graphene layer on an SiC substrate: (1) plasma dry etching after graphitization of the SiC substrate to remove epitaxial graphene monolayers and expose the PG; and (2) direct thermalization in which the graphitization process is managed so that substantially only a pseudo-graphene layer forms on the SiC substrate. In both processes a high-quality PG layer is formed on the SiC substrate.

Advantageously, the methods described do not require exfoliation processes to fabricate the PG/SiC substrate, thereby avoiding problems such as contamination by materials (e.g., Ni) that would otherwise damage the PG surface.

### Direct PG Preparation Methods

Two methods of directly preparing pseudo-graphene are described. In a first method, plasma dry etching is used to remove epitaxial graphene (EG) monolayers formed on the top of pseudo-graphene (PG), and thereby expose and define a PG layer. In a second method, termed a thermalization method, graphitization by Si sublimation is managed so that substantially only a PG layer is formed on the substrate. In this second method, there are no EG monolayers to remove.

Both methods begin with a substrate that has a structure suitable for growing epitaxial III-nitride layers. Particularly, a substrate made of silicon carbide (SiC) is known to provide a strong seed for growth of gallium nitride (GaN), which is a III-nitride material. Other useful III-nitride materials include aluminum nitride (AlN), indium nitride (InN), and boron nitride (BN).

FIG. 1 is a cross-sectional view of an SiC substrate 100 that has been cut to have a flat upper surface 102 upon which the PG layer may be formed. The substrate 100 has any suitable crystal structure such as 4H-SiC (0001) or 6H-SiC (0001). The orientation of the flat surface 102 with respect to the crystal structure may be on-axis or off-axis. ]

### Graphene Structures

Graphene is a two-dimensional form of crystalline carbon. A single sheet (monolayer) of graphene is extremely thin (one atom thick) and has the form of a honeycomb (hexagonal) lattice.

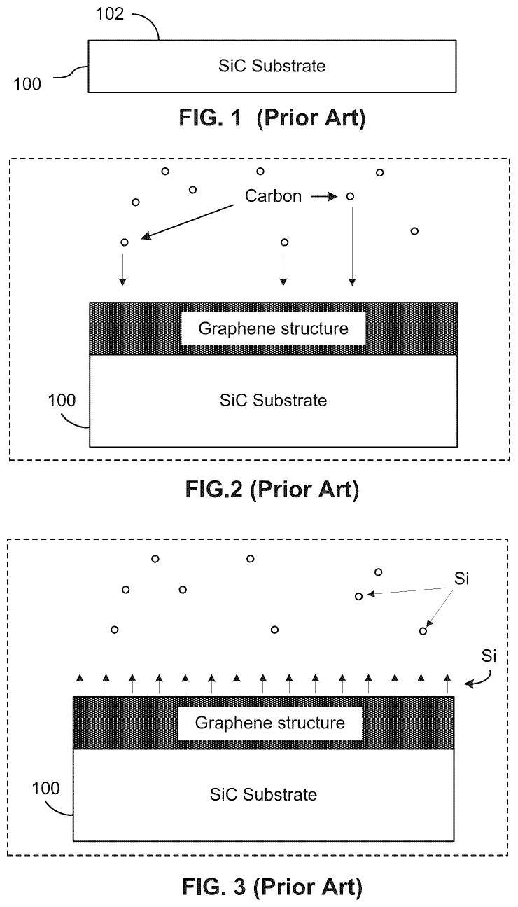

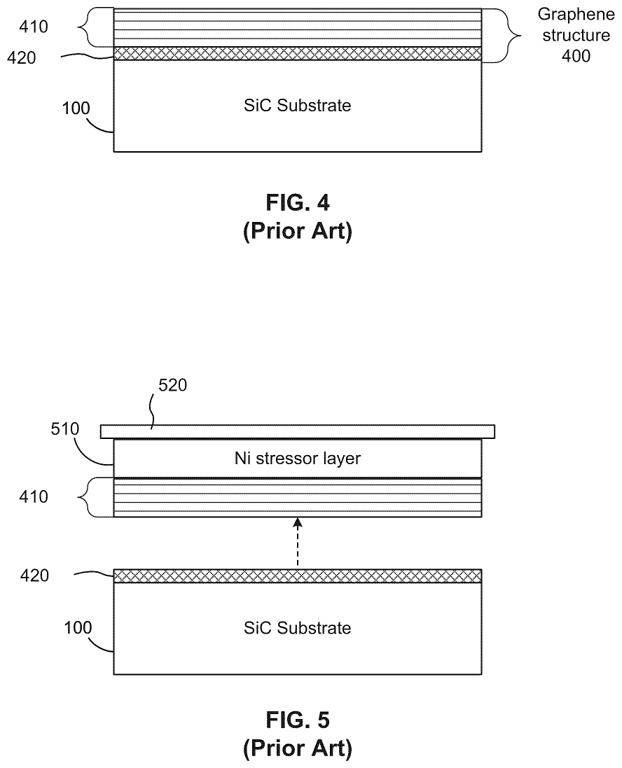

FIGS. 2 and 3 show multilayer graphene structures formed on substrates. For example, as shown in FIG. 2, chemical vapor deposition (CVD) processes may be utilized to deposit carbon atoms on the surface of a substrate, in a manner that forms a multilayer graphene structure 400, as shown in more detail in FIG. 4. A preferred process to create a graphene structure is Si sublimation (FIG. 3), by which the SiC is annealed at a high temperature that causes the Si atoms to sublimate from the SiC material, leaving a mono or multilayer graphene structure 400.

FIG. 4 is a cross-sectional view of a multilayer graphene structure 400 that can be formed using CVD (FIG. 2), Si sublimation (FIG. 3) or any other suitable technique. The multilayer graphene structure 400 includes a graphene layer 410 that includes at least one epitaxially formed graphene (EG) monolayer , the monolayers stacked one on top of the other when more than one is present. However, at the interface between the substrate and graphene layer 410 is a buffer layer comprising a pseudo-graphene (PG) layer 420. The PG layer 420 is connected to the SiC substrate 100 by strong covalent bonds on the SiC substrate side; on the other, exposed side, the PG layer 420 is connected to the adjacent EG monolayer of the graphene layer 410 by a much weaker van der Waal force. Similarly, the stack of EG monolayers is connected to each other by the weaker van der Waal force, and anything formed on the top-most EG monolayer would generally be connected to that layer by the weaker van der Waal force.

It has been recognized that graphene may be useful in semiconductor fabrication. The EG monolayers 410 are removed by exfoliation and the exposed PG layer 420 may be used as a release layer due to the weak van der Waals force on the PG outside surface.

FIG. 5 is a cross-sectional diagram illustrating exfoliation of the graphene layer 410. In conventional processes, the graphene layer may be removed, for example, by Ni-exfoliation. In one conventional process, a nickel (Ni) stressor layer 510 is used to remove the graphene layer 410 . For example, a Ni stressor layer of 500 nm thickness with tensile stress is deposited on the multilayer graphene using plasma sputtering. A thermal release tape 520 is applied on top of the Ni stressor layer 510, and the graphene layer 410 is mechanically exfoliated by lifting the thermal release tap 520, leaving the PG layer 420 exposed. However, this exfoliation process creates stresses due to mechanical removal, and can also introduce contaminants into the PG layer, all of which can impair the quality of the PG surface.

### PG/SiC Substrate by Plasma Etching

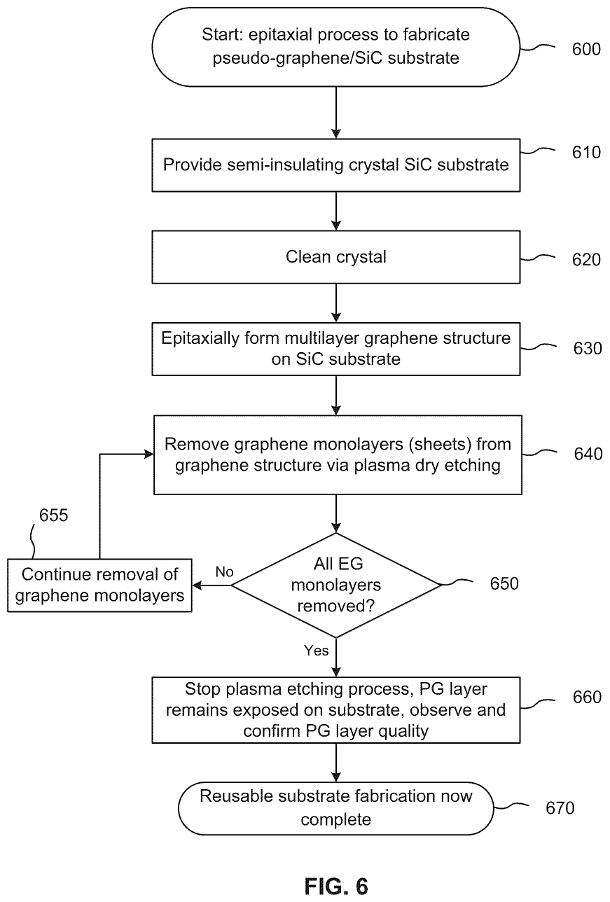

FIG. 6 is a flow chart of steps to epitaxially fabricate a PG/SiC substrate using a plasma dry etching process (STEP 600). An SiC substrate 100 is supplied (STEP 610) which may be, for example, an on-axis or off-axis semi-insulating 4H-SiC (0001) or 6H-SiC (0001) substrate. An on-axis or off-axis semi-insulating 4H-SiC (0001) substrate may be fabricated by cutting and polishing a SiC crystal material at the desired crystal orientation. The substrate 100 may be loaded into a hot-wall CVD reactor for the following steps.

The substrate is then cleaned (STEP 620). For example, the substrate may be cleaned in hydrogen for a time range between about one minute and about 60 minutes (preferably about 15 minutes), and the substrate may also be outgassed in the CVD chamber. The cleaning step is particularly important if the substrate is on-axis. However, if the substrate is off-axis, then cleaning may not be necessary, and the cleaning step may be omitted.

The substrate is graphitized (e.g., in a CVD reactor) to epitaxially form a mono or multilayer graphene structure 400 (STEP 630) utilizing any suitable technique such as those described above. To graphitize the substrate 100 using a Si sublimation approach, the substrate may be annealed in the CVD reactor at temperature in a range of about 1,400° C. to about 2,000° C. (preferably about 1580° C.) in an Argon (Ar) gas ambient within a range of about 10 mbar to about 1,000 mbar (preferably about 100 mbar) for a time range of about one minute to about 60 minutes (preferably about 20 minutes).

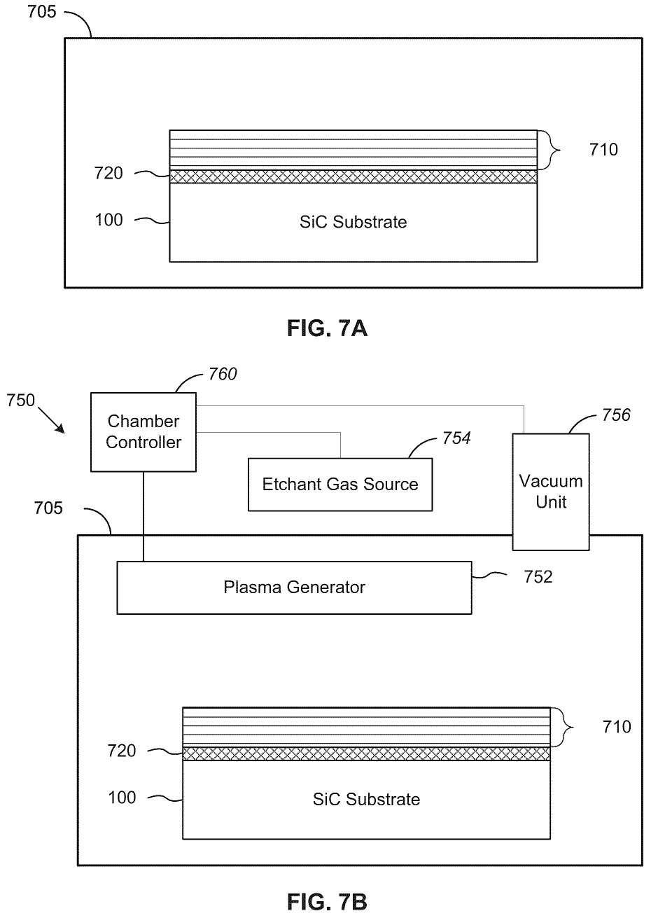

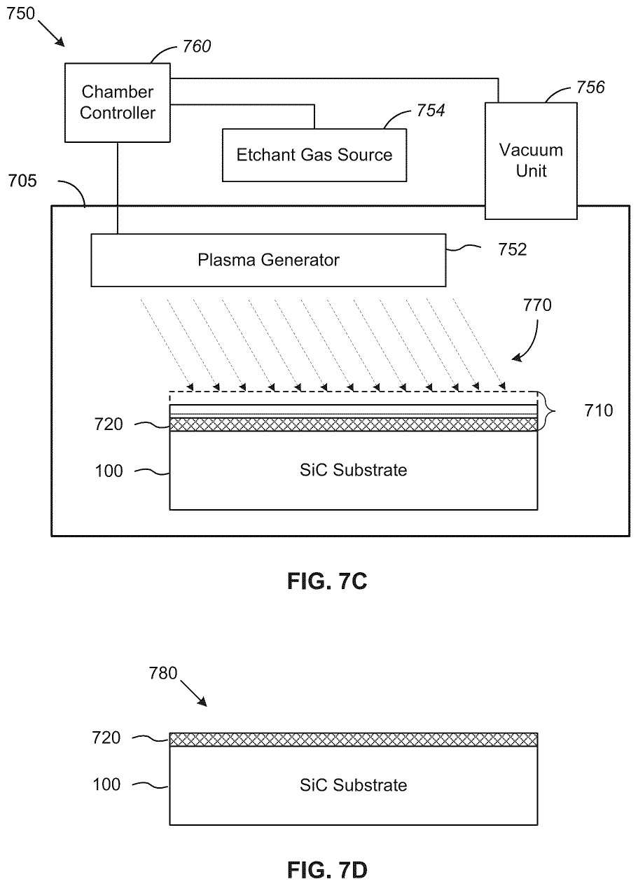

After graphitization (STEP 630) is complete, the graphitized PG/SiC substrate is ready for plasma etching (STEP 640). FIG. 7A shows a graphitized PG/SiC substrate 700 situated in an etching/cleaning chamber 705, for plasma dry etching. Plasma dry etching is preferably performed in an inductively coupled plasma-reactive ion etching (ICP-RIE) system. Generally, plasma cleaning is a process that removes matter from the surface of a substrate through the use of an ionized gas (a plasma). Plasma cleaning is generally performed in a vacuum chamber utilizing oxygen and/or argon gas.

After graphitization (STEP 630 in FIG. 6), the graphitized PG/SiC substrate 700 (FIG. 7A) includes a graphene layer 710 that includes a plurality of epitaxially formed graphene (EG) monolayers, stacked one on top of the other. At the interface between the PG/SiC substrate 700 and graphene layer 710 is a buffer layer comprising a PG layer 720. It may be noted that the PG 720 is covalently bonded to the SiC substrate; particularly, the PG layer 720 is connected to the SiC substrate 100 by strong covalent bonds on the PG/SiC substrate 700 side; on the other side, the PG layer 720 is connected to the adjacent graphene monolayer by a much weaker van der Waal force. Similarly, the EG monolayers in the graphene layer 710 is connected to each other by the weaker van der Waal force.

FIG. 7B is a block diagram that shows components of a plasma etching/cleaning system 750. The plasma etching/cleaning system 750 includes a chamber controller 752 connected to control a plasma generator 754, an etchant gas source 756, and a vacuum unit 758. The etchant gas source 756 is connected to supply etchant gases to the plasma generator 754, and the vacuum unit creates a controllable vacuum in the chamber. The chamber controller 752 controls the plasma generator 754, the flow of etchant gases into the chamber, and the vacuum unit 754 to create the desired processing conditions. FIG. 7B also shows the graphitized substrate 720 situated in the chamber 705 for plasma etching. As will be described, the EG monolayers 710 of on top of the PG layer 720 will be removed by plasma dry cleaning/etching, leaving the PG layer exposed.

FIG. 7C is a block diagram of that illustrates the plasma etching process. Particularly, the monolayers of EG in the graphene layer 710 on top of the PG layer 720, which are held by relatively weak van der Waal forces, are all removed via plasma dry etching under control of the chamber controller 752 using any suitable etching technique. In some embodiments, the layers may be etched in an ALE (atomic layer etching) process, which allows precise control of the etching depth.

The chamber controller 752 controls the power applied to the graphitized substrate by plasma etching to remove the graphene layer 710, while leaving the PG layer 720 remaining at the end of the process. Specifically, the applied power is in a range strong enough to remove the weakly-held EG monolayers, but not strong enough to remove the PG layer. In one example, the graphitized SiC substrate 100 is cleaned with an oxygen plasma for a time range between about 1 minute and about 60 minutes before etching. More generally, an ultra-high purity gas (e.g., oxygen, hydrogen, argon, or nitrogen) may be used as the working (etchant) gas. Electrical power ranged from about 10 W to about 1,000 W is applied to a radio frequency (RF) coil within the plasma generator 752 to generate the oxygen plasma. The RF power to the plasma is in a range from about 1 W to about 100 W. The gas pressure in the chamber is kept at a pressure range from about 10 mTorr to about 1,000 mTorr. Total exposure time to oxygen plasma dry etching may be in the range of about 1 second to about 180 seconds. Oxygen flow rate may be in the range of about 1 sccm to about 100 sccm. In one example, the oxygen flow rate is 400 sccm, the electrical power is about 150 watts, the pressure is about 0.37 mTorr, and the process time is about 60 seconds. In another example, the O₂ flow rate is 10 sccm, the pressure is 50 mTorr, the coil power is 40 watts, the subs power is 10 w, the subs temp is 15° C., and the time is 14 seconds.

The plasma etching process continues until all EG monolayers in the graphene layer 710 have been removed (STEPS 650, 655). For example, in order to confirm that all the EP monolayers have been removed, a Raman spectroscopic analysis may be performed. EP monolayers show distinctive Raman peaks, and therefore when these distinctive Raman peaks are no longer evident, it can be assumed that all the EP monolayers have been removed. Therefore, after plasma etching, the substrate 100 with PG layer 720 may be analyzed using Raman spectroscope methods to determine whether or not essentially all of the EP monolayers have been removed. If Raman spectroscope analysis shows that EP monolayers remain, then the plasma etching process can be repeated until no EP monolayers are evident. As should be clear, other methods of determining essentially full removal of the EP monolayers may be used, including, surface resistance measurement.

FIG. 7D is a cross-sectional view of a PG/SiC substrate 780 after the plasma etching process is complete. The surface of the PG layer 720 is fully exposed (STEP 660), and the PG/SiC substrate 780 may be observed and tested using any suitable techniques to confirm that it meets quality requirements for use as a substrate for epitaxial membrane formation.

The PG/SiC template formation is now complete (STEP 670), and it may now be used and re-used to form epitaxial structures such as GaN structures. Particularly, the exposed van der Waals surface of the PG layer 720 created via these processes provides a PG/SiC template that can be used for repeated growth and release of epitaxial semiconductor membranes, even under the harsh growth conditions experienced during formation of the semiconductor membranes.

### PG/SiC Substrate Only by Thermalization

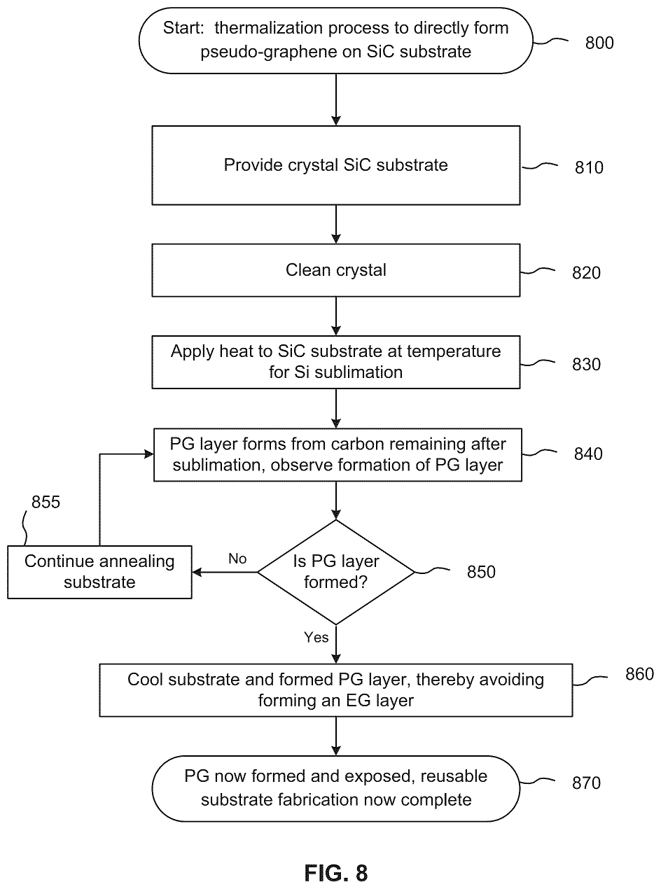

FIG. 8 is flow chart of steps of a process to fabricate a PG/SiC template by utilizing Si sublimation properties and thermalization control and management to directly form a PG layer on an SiC substrate.

An SiC substrate 100 is supplied (STEP 810) which may for example be, for example, an on-axis or off-axis semi-insulating 4H-SiC (0001) or 6H-SiC (0001) substrate. An on-axis or off-axis semi-insulating 4H-SiC (0001) substrate may be fabricated by cutting and polishing an SiC crystal material at the desired crystal orientation. The substrate 100 may be loaded into a hot-wall chemical CVD reactor for the following steps.

The substrate is then cleaned (STEP 820). Particularly, in order to remove polishing damage and residual oxides, the substrate can be exposed to hydrogen etching while at a temperature range from about 1,400° C. to about 2,000° C. (preferably about 1,580° C.) for a time range between about one minute and about 60 minutes (preferably about 15 minutes), and the substate may also be outgassed in the CVD chamber. This cleaning step is particularly important if the substrate is on-axis. However, if the substrate is off-axis, then cleaning may not be necessary, and the cleaning step may be omitted.

As will be explained, a pseudo-graphene layer will be directly grown by controlling and managing the thermal annealing process. Advantageously, this direct growth method does not require additional steps to exfoliate epitaxial graphene monolayers.

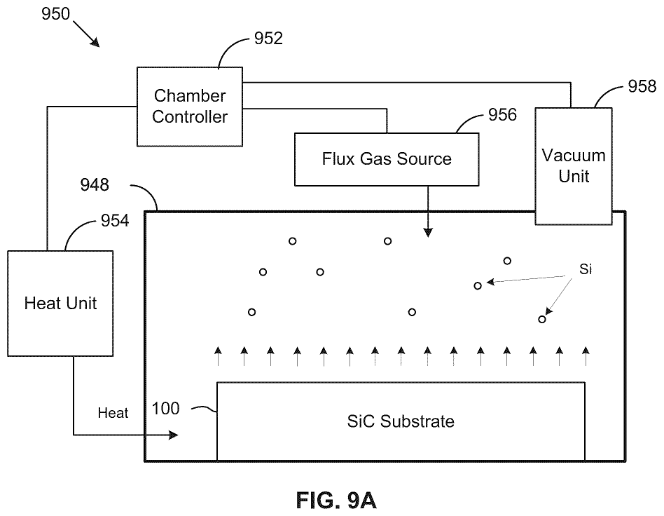

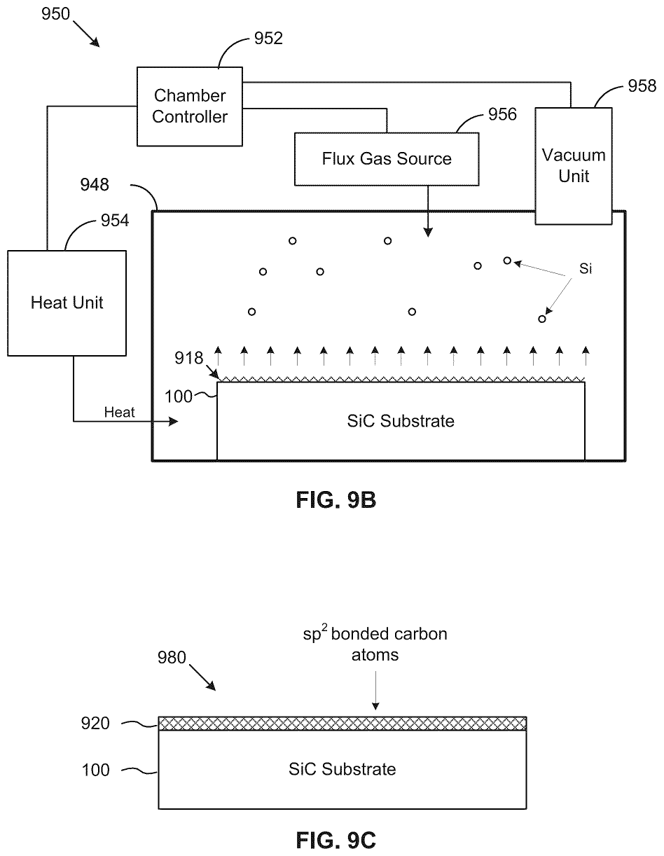

FIG. 9A is a block diagram that shows components of an annealing system 900, illustrating a cleaned SiC substrate 100 situated within an annealing chamber 950. A chamber controller 952 is connected to control a heating unit 954, a flux gas unit 956, and a vacuum unit 959. The flux gas source 956 is connected to supply flux to the chamber 948, and the vacuum unit 958 creates a controllable vacuum in the chamber 950. The chamber controller 952 controls the heat unit 954 to provide the desired temperature in the chamber 950, the flow of flux gases from the flux gas unit 956 into the chamber 950, and the vacuum created by vacuum unit 955 to create the desired processing conditions.

The SiC substrate, now situated in the annealing chamber, is heated to a temperature at which Si sublimation from the substrate begins (STEP 830).

FIG. 9B is a block diagram that shows components of an annealing system, illustrating formation of a PG layer 918 on the upper surface of the SiC substrate 100 while Si sublimation continues (STEP 840). The process is monitored (e.g., for a period of time) and may be controlled as sublimation proceeds, until an appropriate PG layer is formed [STEPS 850, 855] that completely covers the substrate surface. If Si sublimation period is too short then the PG layer 920 will not be formed appropriately, and may not perform well. If the Si sublimation period is too long, then unwanted graphene monolayers may form on the exposed top-side of the PG layer 920, and again the substrate will not perform well. The proper combination of processes is dependent upon a number of factors that vary between embodiments.

Generally, the decomposition of the SiC and creation of the PG layer 920 is controlled by the evaporation of Si atoms, which can be controlled by the chamber conditions.

Particularly, N₂ exposures during annealing may be adjusted as desired to reduce a too fast sublimation rate and provide a smooth decomposition of the SiC substrate 100. Specifically, N₂ fluxes may be used during the sublimation process in order to slow the sublimation rate and provide a smooth decomposition of the SiC substrate 100. In one example, during the PG layer 920 growth process, the SiC substrate 100 is intermittently exposed to higher (but still near-vacuum) N₂ partial pressures ranging between about P=10⁵ Torr to about P=10⁴ Torr while the SiC substrate 100 is being annealed at temperature range of about 1,400° C. to about 2,000° C.

As sublimation of Si atoms continues, and more and more carbon atom are exposed at the upper surface of the SiC substrate 100, it is believed the exposed carbon atoms will rearrange to sp² bonded carbon atoms that are partially covalent bonded to the SiC substrate 100, thus forming the PG layer 920. Directly forming the PG layer 920 on the SiC substrate 100 by a thermalization process is beneficial for simplifying the overall fabrication process of a PG/SiC substrate because it eliminates the otherwise subsequent process of removing epitaxial graphene.

The Si sublimation process continues until a desired PG layer 920 has been fully formed (STEPS 850, 855). In order to confirm that the PG layer 920 is fully formed and no EP monolayers have been formed, a Raman spectroscopic analysis may be performed. As noted above, EP monolayers show distinctive Raman peaks, and therefore when these distinctive Raman peaks are not evident, it can be assumed that no EP monolayers exist.

FIG. 9C is a cross-sectional view of a PG/SiC substrate 980 after the direct PG layer 920 has been formed via the Si sublimation process. The PG/SiC substrate 980 is cooled appropriately to stop sublimation and avoid forming an EG layer (STEP 860). The surface of the PG layer 920 is now fully exposed , and the PG/SiC substrate may be observed and tested using any suitable techniques to confirm that it meets quality requirements for use as a substrate for epitaxial membrane formation.

The PG/SiC template formation is now complete (STEP 870), and it may now be used and re-used to form epitaxial structures such as GaN structures. Particularly, the exposed van der Waals surface of the PG layer 920 created via these processes provides a PG/SiC template that can be used for repeated growth and release of epitaxial semiconductor membranes, even under the harsh growth conditions experienced during formation of the semiconductor membranes.

### Membrane Fabrication and Re-Use

The PG/SiC template described herein is very useful for cost-effectively epitaxially forming free-standing semiconductor membranes, particularly III-N membranes, and then removing the membranes for a variety of uses. For example, such membranes are useful for fabricating many devices, including HEMTs, LEDs, photodiodes, laser diodes, solar cells, light emitting semiconductor chips, as well as other devices that include integrated circuits that include at least one GaN based device components. In application, these devices may include other well-known components such as input terminals, output terminals, a battery or power supply, antennas, transmitters, receivers, displays, memories, and processors.

### PG Layer “After Use” Example

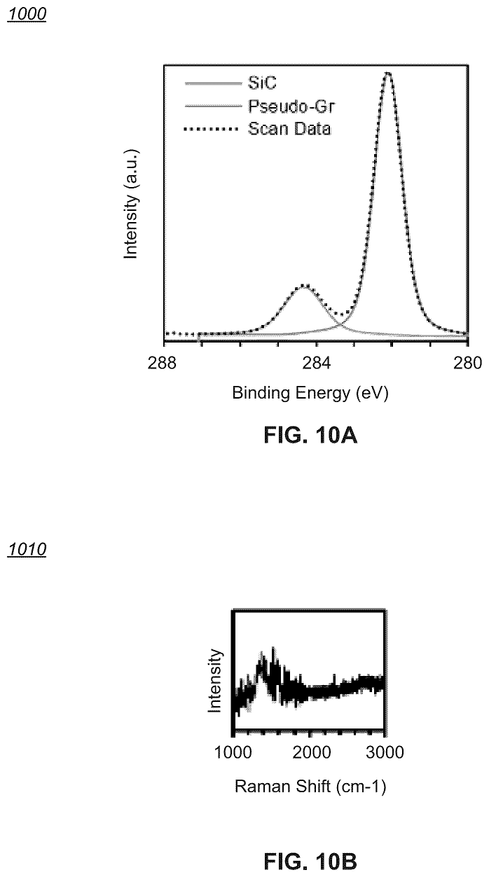

FIG. 10A is a graph 1000 showing the results of a Raman spectrograph analysis of a bare SiC substrate and PG/SiC layer made in accordance with the disclosed methods. FIG. 10B is an associated graph 1010 of intensity as a function of Raman Shift. The PG/SiC substrate was examined after formation of a GaN epilayer and subsequently release (exfoliation) of the GaN epilayer from the PG/SiC substrate. As demonstrated in FIG. 10A, the Raman spectrum of the PG/SiC substrate after exfoliation of GaN epilayers shows the absence of EG, but PG remains on the surface. The selective removal is explained by the fact that the pseudo-graphene is substantially covalently bonded to the substrate.

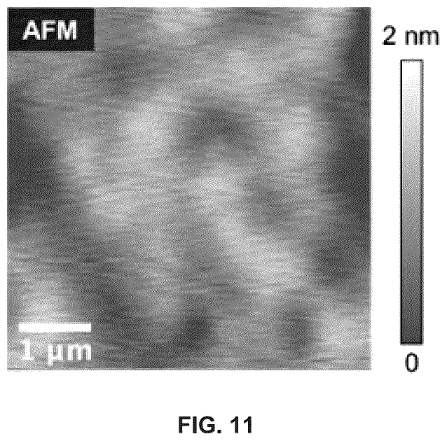

FIG. 11 is an AFM (Atomic Force Microscopy) image of PG/SiC substrate after exfoliation of GaN epilayers. The AFM image shows an essentially undamaged surface due to the full coverage of robust pseudo-graphene on the SiC substrate. This enables reuse of the same PG/SiC substrate without any re-graphitizing or polishing process.

Advantageously, the disclosed processes eliminate the conventional Ni exfoliation process currently used for EG removal, thereby eliminating the potential contamination of the EG during the Ni deposition and subsequent removal (exfoliation) of the EG via mechanical stress. Therefore, the disclosed processes can minimize process defects.

Additionally, the disclosed processes are simple and fabricate a high-quality (theoretically defect-free) pseudo-graphene SiC substrate, which can be reused as a template repeatedly. Due to the essentially atomically flat surface of the reused PG/SiC substrate and the weak van der Waals force on the exposed surface of the PG layer, there is generally no need for wafer refurbishment such as polishing or a regrowth process after exfoliation of semiconductor epilayers from the PG layer. However, if cleaning may be needed, standard wafer cleaning processes may be utilized. In addition, if the PG layer becomes damaged or unusable in some way, the damaged PG layer may be removed (e.g., by plasma etching) and a new PG layer may be formed on the same SiC substrate utilizing the disclosed processes, which has the advantage of saving the cost of a new SiC substrate.

### Conclusion

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A method of fabricating a reusable template for forming semiconductor membranes, comprising:
providing an SiC substrate;
epitaxially forming a graphene structure on the substrate, the graphene structure including
a graphene layer; and
a pseudo-graphene (PG) buffer layer situated between the graphene layer and the substrate; and
using a plasma dry etching process to remove the graphene layer and expose the pseudo-graphene layer without exfoliation, thereby forming a PG/SiC template.

2. The method of claim 1 wherein the plasma dry etching includes applying a predetermined plasma power.

3. The method of claim 2 wherein the predetermined plasma power is in a range that removes the graphene layer and leaves the PG layer substantially intact.

4. The method of claim 3 wherein the plasma dry etching process includes utilizing a working gas of at least one of O₂, H₂, Ar, and N₂.

5. The method of claim 3 wherein PG layer is bonded to the adjacent graphene layer with a van der Waals force, and bonded to the SiC substrate with a covalent force, and further comprising:
selecting a predetermined plasma power greater than the van der Waals force and less than the covalent force.

6. The method of claim 1 wherein the SiC substrate is oriented on-axis.

7. The method of claim 1 wherein the SiC substrate is oriented off-axis.

8. The method of claim 1 wherein the SiC substrate is one of 4-H and 6-H.

9. The method of claim 1 wherein the SiC substrate is 4-H semi-insulating SiC (0001).

10. The method of claim 1 wherein the graphene layer comprises a plurality of graphene monolayers.

11. The method of claim 1 further comprising:
epitaxially forming a membrane comprising GaN on the PG layer of the PG/SiC template; and
releasing the membrane from the PG layer.

12. The method of claim 11 further comprising reusing the same PG/SiC template including:
epitaxially forming a second membrane comprising GaN on the same PG/SiC template; and
releasing the second membrane from the PG layer.

13. A thermalization method of directly forming a PG layer on a SiC substrate to fabricate a reusable PG/SiC template, comprising:
providing an SiC substrate;
heating the SiC substrate to a temperature to sublimate Si from the SiC substrate;
continuing Si sublimation until a PG layer is formed from the carbon; and
stopping the Si sublimation prior to forming a graphene monolayer on the substrate, leaving the PG layer exposed,
thereby providing PG/SiC template.

14. The method of claim 13 wherein the step of Si sublimation includes controlling the sublimation rate with N₂ fluxes.

15. The method of claim 13 wherein the step Si sublimation include controlling the sublimation rate with temperature.

16. The method of claim 13 wherein the SiC substrate is oriented on-axis.

17. The method of claim 13 wherein the SiC substrate is oriented off-axis.

18. The method of claim 13 further comprising utilizing a Raman spectroscope to observe the PG layer.

19. The method of claim 13 further comprising cooling the PG/SiC substrate after PG layer formation, to prevent formation of graphene monolayers.

20. The method of claim 13 further comprising:
epitaxially forming a membrane comprising GaN on the PG layer of the PG/SiC template; and
releasing the membrane from the PG layer.

21. The method of claim 20 further comprising reusing the same PG/SiC template including:
epitaxially forming a second membrane comprising GaN on the same PG/SiC template; and
releasing the second membrane from the PG layer.
